(19) United States
(12) Patent Application Publication
(10) Pub. No.: US 2018/0113803 A1
(43) Pub. Date: Apr. 26, 2018

(54) OPERATION METHOD OF MEMORY CONTROLLER AND OPERATION METHOD OF STORAGE DEVICE INCLUDING THE SAME

(71) Applicant: SAMSUNG ELECTRONICS CO., LTD., SUWON-SI (KR)

(72) Inventors: DAEHYUN KIM, SUWON-SI (KR); BOKYOUNG KIM, HWASEONG-SI (KR); SEONGHOON WOO, HWASEONG-SI (KR)

(21) Appl. No.: 15/706,967

(22) Filed: Sep. 18, 2017

(30) Foreign Application Priority Data
Oct. 24, 2016 (KR) 10-2016-0138578

(51) Int. Cl. G06F 12/02; G06F 3/06; G11C 16/10; G11C 16/26

(52) U.S. Cl. CPC G06F 12/0246; G11C 16/26; G11C 16/10; G06F 3/0659

(57) ABSTRACT

A method, executed by a memory controller, of controlling a nonvolatile memory device having first and second planes includes transmitting a first command included in a command queue to the nonvolatile memory device. A block address of a second command is compared with a block address of a third command, when the third command is queued ahead of the second command in the command queue. The second command is selectively transmitted to the nonvolatile memory device prior to the third command based on the comparison result.

### CROSS-REFERENCE TO RELATED APPLICATIONS

This U.S. non-provisional patent application claims priority under 35 U.S.C. § 119 of Korean Patent Application No. 10-2016-0138578, filed on Oct. 24, 2016, the entire contents of which are hereby incorporated by reference.

### TECHNICAL FIELD

The disclosure relates to semiconductor memory devices, and more particularly, to a method of operating a memory controller and a method of operating a storage device including the memory controller.

### DESCRIPTION OF RELATED ARTS

A semiconductor may be classified into a volatile memory device that loses its stored data when a power supply is interrupted, such as a static random access memory (SRAM), a dynamic random access memory (DRAM), a synchronous DRAM (SDRAM), etc., and a nonvolatile memory device that retains its stored data even when a power supply is interrupted, such as a read only memory (ROM), a programmable ROM (PROM), an electrically programmable ROM (EPROM), an electrically erasable and programmable ROM (EEPROM), a flash memory device, a phase-change RAM (PRAM), a magnetic RAM (MRAM), a ferroelectric RAM (FRAM), and resistive RAM (RRAM), etc.

A flash memory is being widely used as a high-capacity storage medium of a user device. As computing technology develops, more improved performance is required for a flash memory-based high-capacity storage medium. Various techniques or devices are being developed to improve performance of the flash memory-based high-capacity storage medium.

### SUMMARY

Example embodiments of the disclosure provide a method, executed by a memory controller, of controlling a nonvolatile memory device having first and second planes. The method may include transmitting a first command included in a command queue to the nonvolatile memory device. A block address of a second command is compared with a block address of a third command when the third command is ahead of the second command in the command queue. The second command is selectively transmitted to the nonvolatile memory device prior to the third command based on the comparison result. The first command is a command with respect to the first plane, the second command is a command with respect to the second plane, and the third command is a multi-plane command with respect to the first and second planes.

Example embodiments of the disclosure provide a method executed by a storage device having a memory controller and a nonvolatile memory device, which includes first and second planes. The method may include processing a first command included in a command queue of the memory controller. A block address of a second command is compared with a block address of a third command when the third command is ahead of the second command. The second command is processed prior to the third command according to the comparison result. The first command is a command with respect to the first plane, the second command is a command with respect to the second plane, and the third command is a command with respect to the first and second planes.

Example embodiments of the disclosure provide a method, executed by a memory controller, of controlling a nonvolatile memory device having first and second planes. The method may include transmitting a first command, addressing the first plane, to the nonvolatile memory device and transmitting a second command, addressing the second plane, to the nonvolatile memory device before receiving a response to the first command from the nonvolatile memory device.

Example embodiments of the disclosure provide a method executed by a storage device having a memory controller and a nonvolatile memory. The method includes communicating a first command from the memory controller to the nonvolatile memory, the first command having a highest execution priority within a command queue of the memory controller. When a second command having the next-highest priority, to that of the first command, within the command queue is addressed to the same plane of the nonvolatile memory as is the first command, the method includes communicating a third command, within the command queue, from the memory controller to the nonvolatile memory that is not addressed to the same plane of the nonvolatile memory as is the first command Otherwise, the second command is communicated from the memory controller to the nonvolatile memory.

### BRIEF DESCRIPTION OF THE FIGURES

Embodiments of the disclosure will be described below in more detail with reference to the accompanying drawings. The embodiments of the disclosure may, however, be embodied in different forms and should not be construed as limited to the embodiments set forth herein. Rather, these embodiments are provided so that this disclosure will be thorough and complete, and will fully convey the scope of the disclosure to those skilled in the art. Like numbers refer to like elements throughout.

FIG. 1 is a block diagram illustrating a storage device according to example embodiments of the disclosure.

FIG. 2 is a block diagram illustrating a memory controller of FIG. 1 in detail.

FIG. 3 is a block diagram illustrating a nonvolatile memory device of FIG. 1.

FIG. 4 is a view illustrating a memory block of FIG. 3.

FIG. 5 is a flowchart illustrating a command scheduling method according to example embodiments of the disclosure.

FIG. 6 is a view for explaining an illustrative command type according to example embodiments of the disclosure.

FIG. 7 is a view for explaining an operation method of FIG. 5.

FIG. 8 is a flowchart illustrating another embodiment of an operation method of a command scheduler of FIG. 1.

FIG. 9 is a view for explaining an operation method of FIG. 8.

FIG. 10 is a flowchart illustrating another embodiment of an operation method of a command scheduler of FIG. 1.

FIG. 11 is a view for explaining an operation method of FIG. 10.

FIG. 12 is a view for explaining a different operation of a command scheduler of FIG. 1.

FIG. 13 is a flowchart illustrating a different operation of a command scheduler of FIG. 1.

FIG. 14 is a block diagram illustrating a nonvolatile memory device according to other example embodiments of the disclosure.

FIG. 15 is a view for explaining a scheduling method with respect to a command being provided to a nonvolatile memory device illustrated in FIG. 14.

FIG. 16 is a view illustrating a storage device according to example embodiments of the disclosure.

FIG. 17 is a view for explaining a command scheduling method with respect to a storage device of FIG. 16.

FIG. 18 is a block diagram illustrating an SSD (solid state drive) system to which the disclosure is applied.

### DETAILED DESCRIPTION OF THE EMBODIMENTS

Below, embodiments of the disclosure may be described in detail and clearly to such an extent that an ordinary one in the art easily implements the disclosure.

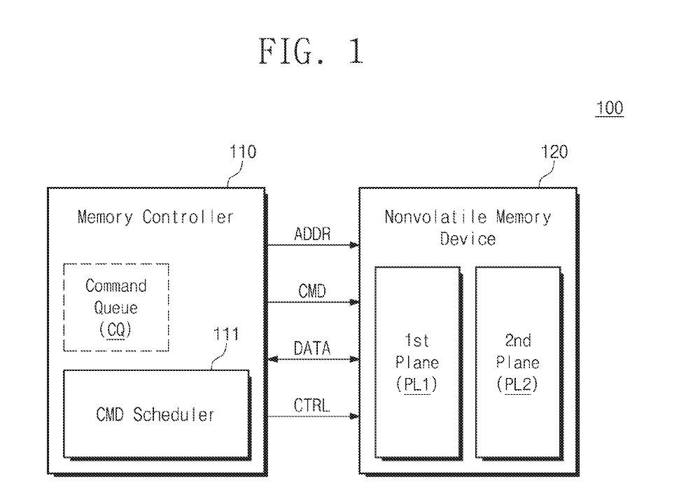

FIG. 1 is a block diagram illustrating a storage device according to example embodiments of the disclosure. Referring to FIG. 1, a storage device 100 may include a memory controller 110 and a nonvolatile memory device 120. The storage device 100 may be a high-capacity storage medium, such as a solid state drive (SSD), a memory card, a memory stick, etc.

The memory controller 110 may read data stored in the nonvolatile memory device 120 or may store data in the nonvolatile memory device 120 according to a request from an external device (e.g., host, CPU, AP, etc.). For example, the memory controller 110 may provide an address ADDR, a command CMD, and a control signal CTRL to the nonvolatile memory device 120 and may exchange data, DATA, with the nonvolatile memory device 120.

The nonvolatile memory device 120 may output stored data or may store received data in response to a signal received from the memory controller 110. It is assumed that the nonvolatile memory device 120 is a NAND-type flash memory device. However, the scope of the disclosure is not limited thereto and the nonvolatile memory device 120 may include a volatile memory, such as a static random access memory (SRAM), a dynamic random access memory (DRAM), a synchronous DRAM (SDRAM), etc., and a nonvolatile memory, such as a read only memory (ROM), a programmable ROM (PROM), an electrically programmable ROM (EPROM), an electrically erasable and programmable ROM (EEPROM), a phase-change RAM (PRAM), a magnetic RAM (MRAM), a ferroelectric RAM (FRAM), a resistive RAM (RRAM), a TRAM (thyristor RAM), etc.

The nonvolatile memory device 120 may include first and second planes (PL1, PL2). Each of the first and second planes (PL1, PL2) may include a plurality of memory blocks. The plurality of memory blocks included in the first plane PL1 may share the same bit lines and the plurality of memory blocks included in the second plane PL2 may share the same bit lines.

In example embodiments, the nonvolatile memory device 120 may perform an independent operation on each of the first and second planes (PL1, PL2) under the control of the memory controller 110. For example, the nonvolatile memory device 120 may perform a first operation on at least some of the plurality of memory blocks included in the first plane PL1 under the control of the memory controller 110. While the first operation is performed, the nonvolatile memory device 120 may perform a second operation on at least some of the plurality of memory blocks included in the second plane PL2 under the control of the memory controller 110. That is, the nonvolatile memory device 120 may perform an independent operation by planes.

In example embodiments, the memory controller 110 may provide commands for an operation of the nonvolatile memory device 120. The memory controller 110 may provide a first plane command, a second plane command, or a multi plane command. The first plane command may indicate a command with respect to a memory block included in the first plane PL1, the second plane command may indicate a command with respect to a memory block included in the second plane PL2, and the multi plane command may indicate a command with respect to both a memory block included in the first plane PL1 and a memory block included in the second plane PL2.

The nonvolatile memory device 120 may perform an operation on a memory block included in the first plane PL1 in response to the first plane command, may perform an operation on a memory block included in the second plane PL2 in response to the second plane command, and may perform an operation on both a memory block included in the first plane PL1 and a memory block included in the second plane PL2 in response to the multi plane command. As described above, performance of the storage device (e.g., performance with respect to random I/O) may be improved by performing, by the nonvolatile memory device 120, an independent operation on each plane.

In example embodiments, the memory controller 110 may include a command scheduler 111. The command scheduler 111 may manage a command from an external device (e.g., host) to improve performance of the storage device 100.

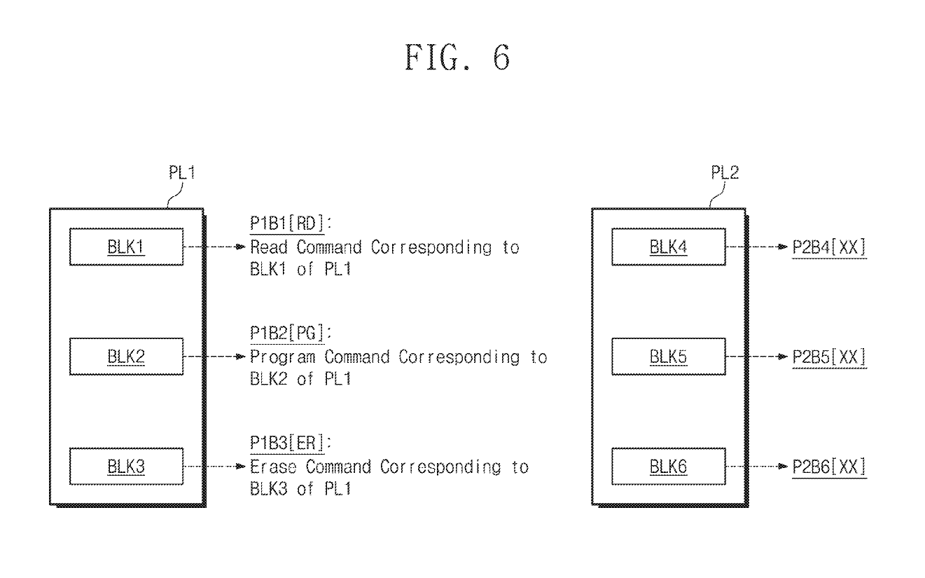

The commands may be queued in a command queue (CQ). The commands may include the first plane command, the second plane command, or the multi-plane command. The command scheduler 111 may provide the first plane command, the second plane command, or the multi-plane command to the nonvolatile memory device 120 in an in-order manner or an out-of-order manner according to a scheduling method of the disclosure. According to a scheduling method of the command scheduler 111, the first plane command and the second plane command may be provided to the nonvolatile memory device 120 differently from the order queued in the command queue (CQ). In this case, since the nonvolatile memory device 120 can perform operations on the first and second planes (PL1, PL2) at the same time or to be overlapped with each other, performance of the storage device 100 may be improved. The scheduling method according to the disclosure will be described in further detail with reference to FIGS. 6 through 17.

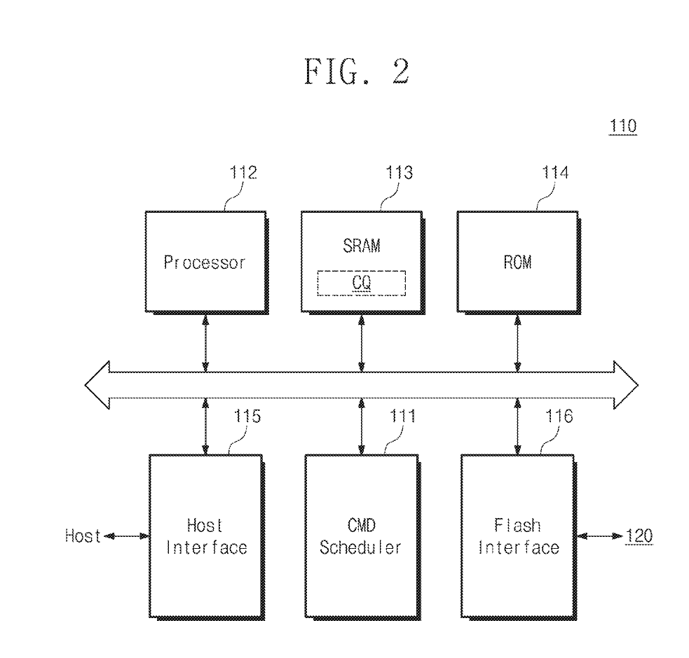

FIG. 2 is a block diagram illustrating a memory controller of FIG. 1 in detail. Referring to FIGS. 1 and 2, the memory controller 110 may include a command scheduler 111, a processor 112, an SRAM 113, a ROM 114, a host interface 115, and a flash interface 116. Although not illustrated in the drawing, the memory controller 110 may further include other configuration elements such as a randomizer, an error correction circuit, etc.

The command scheduler 111 may be configured to schedule commands queued in the command queue (CQ). The processor 112 may control an overall operation of the memory controller 110. The SRAM 113 may be used as a buffer memory, a cache memory, or a main memory of the memory controller 110. The RAM 114 may store various information required when the memory controller 110 operates in the form of firmware. In example embodiments, information about commands included in the command queue (CQ) may be stored in the SRAM 113.

In example embodiments, the command scheduler 111 may be provided in the form of software or hardware. The command scheduler 111 provided in the form of software may be stored in the SRAM 113 and may be driven by the processor 112.

The memory controller 110 may communicate with an external device (e.g., host) through the host interface 115. As an example, the host interface 115 may include at least one of a DDR (double data rate) interface, a USB (universal serial bus) interface, an MMC (multimedia card) interface, an eMMC (embedded MMC) interface, a PCI (peripheral component interconnection) interface, a PCI-E (PCI-express) interface, an ATA (advanced technology attachment) interface, a serial-ATA interface, a parallel-ATA interface, an SCSI (small computer small interface) interface, an ESDI (enhanced small disk interface) interface, an IDE (integrated drive electronics) interface, a Firewire interface, a UFS (universal flash storage) interface, an NVMe (nonvolatile memory-express) interface, etc. The memory controller 110 may communicate with the nonvolatile memory device 120 through the flash interface 116.

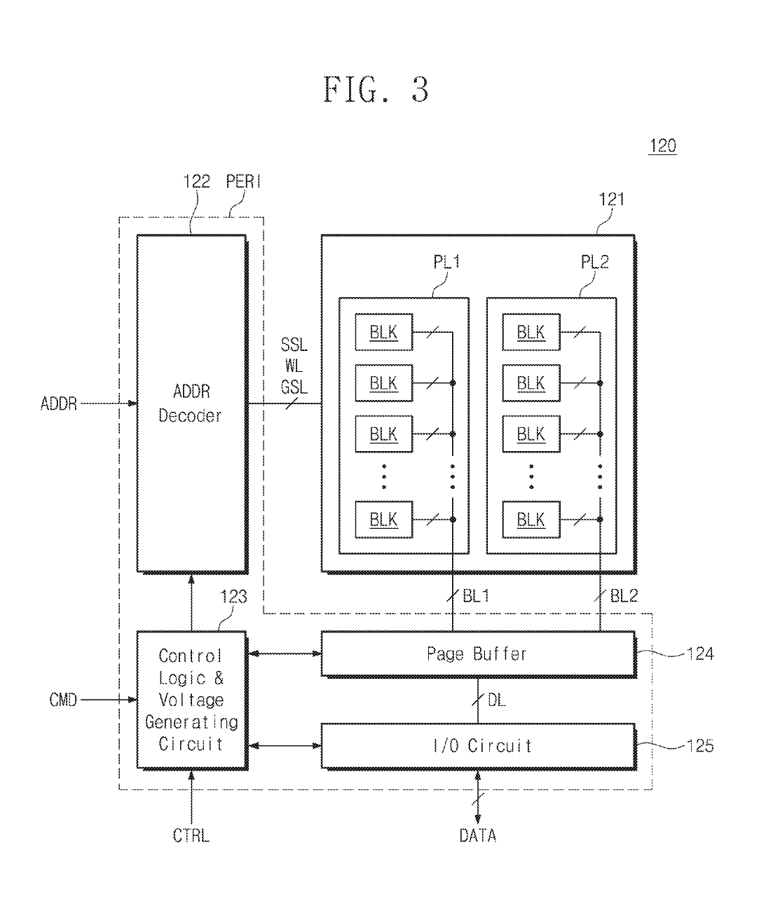

FIG. 3 is a block diagram illustrating a nonvolatile memory device of FIG. 1. Referring to FIGS. 1 and 3, the nonvolatile memory device 120 may include a memory cell array 121 and a peripheral circuit PERI.

The memory cell array 121 may include the first and second planes (PL1, PL2). Each of the first and second planes (PL1, PL2) may include a plurality of memory blocks BLK. Each of the memory blocks BLK included in each of the first and second planes (PL1, PL2) may be connected to the peripheral circuit PERI through string selection lines SSL, word lines WL, and ground selection lines GSL.

The memory blocks BLK included in the first plane PL1 may be connected to the peripheral circuit PERI through first bit lines BL1. That is, the memory blocks BLK included in the first plane PL1 may share the first bit lines BL1. The memory blocks BLK included in the second plane PL2 may be connected to the peripheral circuit PERI through second bit lines BL2. That is, the memory blocks BLK included in the second plane PL2 may share the second bit lines BL2.

The peripheral circuit PERI may receive an address ADDR, a command CMD, and a control signal CTRL from the memory controller 110 and may exchange data with the memory controller 110 in response to the received signal. For example, the peripheral circuit PERI may include an address decoder 122, a control logic & voltage generation circuit 123, a page buffer 124, and an input/output circuit 125.

The address decoder 122 is connected to the memory cell array 121 through string selection lines SSL, word lines WL, and ground selection lines GSL. The address decoder 122 may receive the address ADDR from the memory controller 110 and may decode the received address ADDR. The address decoder 122 can control at least one word-line voltage based on the decoded address.

The control logic & voltage generation circuit 123 may receive the command CMD and the control signal CTRL from the memory controller 110 and may control the address decoder 122, the page buffer 124, and the input/output circuit 125 in response to the received signals. The control logic & voltage generation circuit 123 may generate various voltages required when the nonvolatile memory device 120 operates.

The page buffer 124 is connected to the memory blocks BLK included in the first plane PL1 through the first bit lines BL1 and is connected to the memory blocks BLK included in the second plane PL2 through the second bit lines BL2. The page buffer 124 may temporarily store data to be stored in the memory cell array 121 or data read from the memory cell array 121.

The input/output circuit 125 may be connected to the page buffer 124 through data lines DL and may exchange data with the page buffer 124 through the data lines DL. The input/output circuit 125 may transmit data to the memory controller 110 or may receive data from the memory controller 110 under the control of the control logic & voltage generation circuit 123.

The configuration elements included in the peripheral circuit PERI may be configured to independently perform an operation on the first plane PL1, an operation on the second plane PL2, or an operation on the first and second planes (PL1, PL2) (i.e., a multi-plane operation) in response to signals received from the memory controller 110.

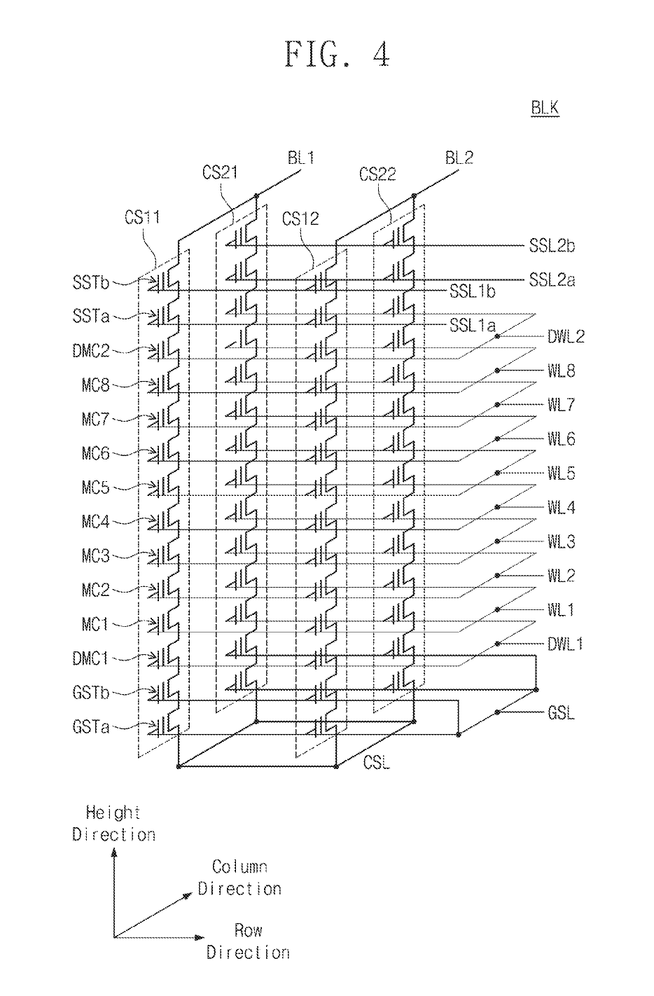

FIG. 4 is a view illustrating a memory block of FIG. 3. As an example, although a memory block having a three-dimensional structure is described with reference to FIG. 4, the scope of the disclosure is not limited thereto. The memory block according to the disclosure may have a memory block of a two-dimensional structure (i.e., a planar structure). The memory block illustrated in FIG. 4 may be a physical erase unit of the nonvolatile memory device 120. However, the scope of the disclosure is not limited thereto and a physical erase unit of the nonvolatile memory device 120 may be changed to a page unit, a word line, a sub block unit, etc.

Referring to FIG. 4, a memory block BLK includes a plurality of cell strings (CS11, CS12, CS21, CS22). The cell strings (CS11, CS12, CS21, CS22) may be arranged along a row direction and a column direction to form rows and columns.

Each of the cell strings (CS11, CS12, CS21, CS22) includes a plurality of cell transistors. For example, each of the cell strings (CS11, CS12, CS21, CS22) may include string selection transistors (SSTa, SSTb), a plurality of memory cells (MC1 to MC8), ground selection transistors (GSTa, GSTb), and dummy memory cells (DMC1, DMC2). Each of the plurality of cell transistors included in the cell strings (CS11, CS12, CS21, CS22) may be a charge trap flash (CTF) memory cell.

The plurality of memory cells (MC1 to MC8) are serially connected to one other and are laminated in a height direction perpendicular to a plane formed by a row direction and a column direction. The string selection transistors (SSTa, SSTb) are serially connected to each other and are provided between the memory cells (MC1 to MC8) and the bit lines BL1 and BL2. The ground selection transistors (GSTa, GSTb) are serially connected to each other and are provided between the memory cells (MC1 to MC8) and a common source line CLS.

In example embodiments, the first dummy memory cell DMC1 may be provided between the memory cells (MC1 to MC8) and the ground selection transistors (GSTa, GSTb) and the second dummy memory cell DMC2 may be provided between the memory cells (MC1 to MC8) and the string selection transistors (SSTa, SSTb).

In example embodiments, the ground selection transistors (GSTa, GSTb) of the cell strings (CS11, CS12, CS21, CS22) may be connected to the ground select line GSL in common. In example embodiments, although not illustrated in the drawing, ground selection transistors of the same row may be connected to the same ground selection line and ground selection transistors of different rows may be connected to different ground selection lines respectively. For example, the first ground selection transistors GSTa of the cell strings (CS11, CS12) of a first row may be connected to a first ground selection line and the first ground selection transistors GSTa of the cell strings (CS21, CS22) of a second row may be connected to a second ground selection line.

In example embodiments, although not illustrated in the drawing, ground selection transistors provided at the same height from a substrate (not shown) may be connected to the same ground selection line and ground select transistors provided at different heights from the substrate may be connected to different ground select lines respectively.

Memory cells positioned at the same height from the substrate or the ground selection transistors (GSTa, GSTb) may be connected to the same word line in common and memory cells positioned at different heights from the substrate or the ground selection transistors (GSTa, GSTb) may be connected to different word lines respectively. For example, the first through eighths memory cells (MC1 to MC8) of the cell strings (CS11, CS12, CS21, CS22) are connected to the first through eighth word lines (WL1 to WL8) respectively in common.

String selection transistors of the same row among the first string transistors SSTa of the same height are connected to the same string selection line and string selection transistors of different rows among the first string transistors SSTa of the same height are connected to different string selection lines respectively. For example, the first string selection transistors SSTa of the cell strings (CS11, CS12) of the first row are connected to a string selection line SSL1a in common and the first string selection transistors SSTa of the cell strings (CS21, CS22) of the second row are connected to a string select line SSL2a in common.

Similarly, string selection transistors of the same row among the second string selection transistors SSTb of the same height are connected to the same string selection line and string selection transistors of different rows among the second string selection transistors SSTb of the same height are connected to different string selection lines respectively. For example, the second string selection transistors SSTb of the cell strings (CS11, CS12) of the first row are connected to a string selection line SSL1b in common and the second string selection transistors SSTb of the cell strings (CS21, CS22) of the second row are connected to a string selection line SSL2b in common.

Dummy memory cells of the same height are connected to the same dummy word line and dummy memory cells of different heights are connected to different dummy word lines respectively. For example, the first dummy memory cells DMC1 are connected to a first dummy word line DWL1 and the second dummy memory cells DMC2 are connected to a second dummy word line DWL2.

The memory block BLK illustrated in FIG. 4 is illustrative and the number of cell strings may increase or decrease. The number of rows and columns constituted by the cell strings may increase or decrease depending on the number of cell strings. The number of cell transistors (GST, MC, DMC, SST, etc.) of the memory block BLK may also increase or decrease and a height of the memory block BLK may increase or decrease depending on the number of cell transistors. The number of lines (GSL, WL, DWL, SSL, etc.) connected to the cell transistors may increase or decrease depending on the number of cell transistors.

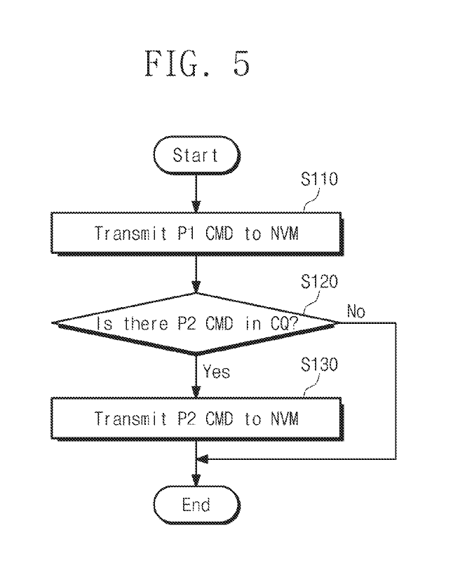

FIG. 5 is a flowchart illustrating a command scheduling method according to example embodiments of the disclosure. For brevity of drawings and convenience of description, a command with respect to a memory block of the first plane PL1 is referred to as a “P1 command”, a command with respect to a memory block of the second plane PL2 is referred to as a “P2 command”, and a multi-plane command with respect to memory blocks of the first and second planes (PL1, PL2) is referred to as an “MP command”.

That is, the nonvolatile memory device 120 may perform an operation (e.g., a read operation, a write operation, or an erase operation) with respect to memory blocks included in the first plane PL1 in response to the P1 command. The nonvolatile memory device 120 may perform an operation on memory blocks included in the second plane PL2 in response to the P2 command. The nonvolatile memory device 120 may perform an operation on memory blocks included in the first and second planes (PL1, PL2) at the same time in response to the MP command.

For convenience of description, in the embodiments of the disclosure, a read, program, or erase operation on a specific memory block is performed in response to a specific command. However, this is only for convenience of description and this may mean that a program operation, a read operation or an erase operation on at least one memory block, at least one page of the at least one memory block, or at least one word-line connected to the at least one memory block is performed in response to the specific command.

It is assumed that the commands mentioned in the specification or the commands illustrated in the drawing are queued in the command queue (CQ) of FIG. 1 in advance.

Referring to FIGS. 1 and 5, in an operation S110, the command scheduler 111 may transmit the P1 command to the nonvolatile memory device 120. For example, the command scheduler 111 may transmit the P1 command among commands queued in the command queue (CQ) to the nonvolatile memory device 120 according to a queueing order.

The nonvolatile memory device 120 may perform an operation on a memory block included in the first plane PL1 in response to the received P1 command. The memory block described above may be a memory block corresponding to a physical address of the P1 command.

In an operation S120, the command scheduler 111 may determine whether there exists the P2 command in the command queue (CQ). For example, the command queue (CQ) may include various commands such as the P1 command, the P2 command, or the MP command. The command scheduler 111 may determine whether there exists the P2 command in commands included in the command queue (CQ).

In the case where there exists the P2 command in the command queue (CQ), in an operation S130, the command scheduler 111 may transmit the P2 command to the nonvolatile memory device 120. For example, the command scheduler 111 may transmit the P2 command to the nonvolatile memory device 120 while the nonvolatile memory device 120 performs an operation on the P1 command (i.e., before an operation corresponding to the P1 command is completed). The nonvolatile memory device 120 may perform an operation on a memory block included in the second plane PL2 in response to the received P2 command In this case, the operation on a memory block included in the first plane PL1 and an operation and the operation on a memory block included in the second plane PL2 may be performed at the same time or to be overlapped with each other.

In the case where there does not exist the P2 command in the command queue (CQ), the command scheduler 111 may not perform a separate operation.

In example embodiments, although not illustrated in the drawing, after the nonvolatile memory device 120 completes an operation on the P1 command, the command scheduler 111 may transmit other P1 commands included in the command queue (CQ) to the nonvolatile memory device 120.

As described above, in the case where commands (e.g., the P1 command and the P2 command) with respect to different planes exist in the command queue (CQ), the command scheduler 111 may transmit the P1 command and the P2 command to the nonvolatile memory device 120 regardless of the queueing order. Performance of the storage device 100 is improved by performing operations with respect to the P1 command and the P2 command at the same time or to be overlapped with each other.

FIG. 6 is a view for explaining an illustrative command type according to example embodiments of the disclosure. Referring to FIG. 6, a nonvolatile memory device 120 may include first and second planes (PL1, PL2). The first plane PL1 may include first through third memory blocks (BLK1, BLK2, BLK3) and the second plane PL2 may include fourth through sixth memory blocks (BLK4, BLK5, BLK6). However, the scope of the disclosure is not limited thereto and the nonvolatile memory device 120 may include a plurality of planes and each of the planes may include a plurality of memory blocks.

A read command with respect to the first memory block BLK1 of the first plane PL1 is called “P1B1[RD] command” In response to the P1B1[RD] command, the nonvolatile memory device 120 may perform a read operation on at least one page of a plurality of pages included in the first memory block BLK1 of the first plane PL1. At least one page may be a page corresponding to an address of the P1B1 [RD] command.

A program command with respect to the second memory block BLK2 of the first plane PL1 is called “P1B2[PG] command” An erase command with respect to the third memory block BLK3 of the first plane PL1 is called “P1B3[ER] command” Similarly, commands with respect to fourth through sixth memory blocks (BLK4, BLK5, BLK6) are called “P2B4[XX]” command”, “P2B5[XX] command”, and “P2B6[XX] command” respectively. The “XX” symbol indicates “RD”, “PG”, or “ER” and may be variously replaced according to the type of command.

The commands described above are exemplary, so as to clearly describe the embodiments of the disclosure. However, the commands are not a command set that is in common use and, the scope of the disclosure is not limited thereto. Reference symbols of the commands may be variously changed depending on a target memory block, the type of command, etc. For example, an erase command with respect to the fifth memory block BLK5 of the second plane PL2 may be referred to as “P2B5[ER] command”.

Although not illustrated in the specification or drawings, the aforementioned commands may be generated by a flash translation layer (FTL) of the memory controller 110 based on a request of an external device or an internal management operation.

To briefly and clearly describe embodiments of the disclosure, the embodiments of the disclosure are described based on the reference symbols of the command described with reference to FIG. 6.

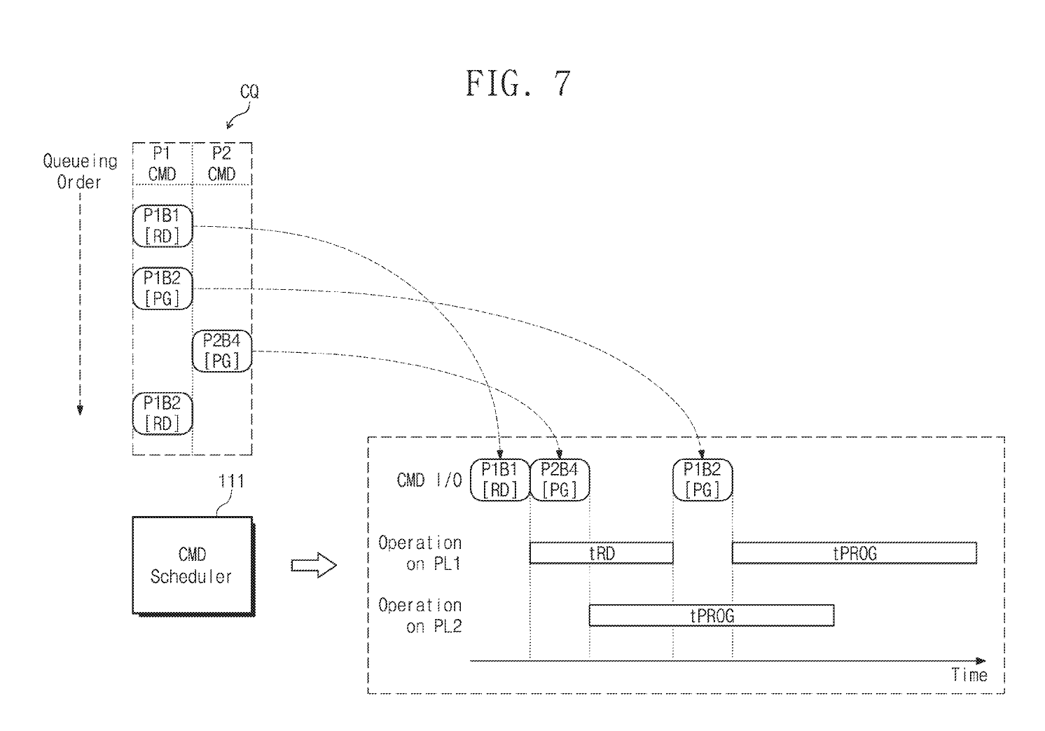

FIG. 7 is a view for explaining an operation method of FIG. 5. For brevity of drawings, configuration elements which are not necessary for describing an operation of the command scheduler 111 are omitted.

Referring to FIGS. 5 through 7, each command may be queued in the command queue (CQ) in the order of the P1B1[RD] command, the P1B2[PG] command, the P2B4[PG] command, and the P1B2[RD] command.

The queueing order described above takes into account only the lapse of time (e.g., time taken for a command to be queued). However, the scope of the disclosure is not limited thereto and the queueing order of commands may be queued in various ways (e.g., priority way, quality of service, etc.). As an example, after the P2B4[PG] command is queued in the command queue (CQ) first, the P1B1[RD] command and the P1B2[PG] command that have higher priority than the P2B4[PG] command may be issued. In this case, since the P1B1[RD] command and the P1B2[PG] command have high priority, the command queue (CQ) may be arranged such that the P1B1[RD] command and the P1B2[PG] command are performed first. The priority queueing way is merely an example and the scope of the disclosure is not limited thereto. It will be well understood by one of ordinary skill in the art that the queueing order in the command queue (CQ) may be arranged in various ways. For convenience of description and clarity of embodiments, it is assumed that commands in the command queue (CQ) are arranged based on the time when they are queued.

A command arrangement illustrated in FIG. 7 is described so as to simply distinguish planes corresponding to commands and does not mean a technical configuration such as priority of commands, a queuing order of commands, etc. For example, in the command queue (CQ) illustrated in FIG. 7, the P1B1[RD] command, the P1B2[PG] command, the P1B2[RD] command correspond to the P1 command and the P2B4[PG] command corresponds to the P2 command. This arrangement and configuration may have a similar meaning in similar drawings below.

It is also assumed that a queueing order of commands has an order of a dotted line direction illustrated in the drawing. That is, the dotted line illustrated in the drawing means that after the P1B1[RD] command is queued in the command queue (CQ), the P1B2[PG] command is queued, and the dotted line indicating a queueing order may have a similar meaning in similar drawings below.

A conventional command scheduler may sequentially transmit commands in the command queue (CQ) to the nonvolatile memory device 120 in the order of being queued. However, the command scheduler 111 according to the disclosure may provide commands to the nonvolatile memory device 120 according to the operation method described with reference to FIG. 5.

For example, the command scheduler 111 may provide the P1B1[RD] command first queued to the nonvolatile memory device 120 through a command I/O. The nonvolatile memory device 120 may perform a corresponding operation (i.e., a read operation corresponding to a time tRD) on the first plane PL1 in response to the P1B1 [RD] command.

A conventional memory controller may provide the P1B2[RD] command to the nonvolatile memory device 120 after an operation on the P1B1[RD] command is completed and may provide the P2B4[PG] command to the nonvolatile memory device 120 after an operation on the P1B2[RD] command is completed according to a queueing order.

However, the command scheduler 111 may transmit the P2B4[PG] command which is a command with respect to the second plane PL2 to the nonvolatile memory device 120 after transmitting the P1B1[RD] command to the nonvolatile memory device 120. That is, while the nonvolatile memory device 120 performs an operation (i.e., corresponding to time tRD) on the P1B1[RD] command, the command scheduler 111 may provide the P2B4[PG] command to the nonvolatile memory device 120. The command scheduler 111 may provide the P2B4[PG] command to the nonvolatile memory device 120 before receiving a response or read data to the P1B1[RD] command from the nonvolatile memory device 120. The nonvolatile memory device 120 may perform a program operation (i.e., corresponding to a time tPROG) on the fourth memory block BLK4 of the second plane PL2 in response to the P2B4[PG] command.

After the nonvolatile memory device 120 completes an operation on the P1B1[RD] command, the command scheduler 111 may provide the P1B2[PG] command to the nonvolatile memory device 120. The nonvolatile memory device 120 may perform a program operation (i.e., corresponding to a time tPROG) on the second memory block BLK2 of the first plane PL1 in response to the P1B2[PG] command.

As described above, the command scheduler 111 may provide commands in the command queue (CQ) to the nonvolatile memory device 120 differently from the order of being queued (i.e., an out-of-order manner) and thereby the nonvolatile memory device 120 may perform an operation on each of the first and second planes (PL1, PL2) at the same time or to be overlapped with each other. Thus, overall operation performance of the storage device 100 may be improved.

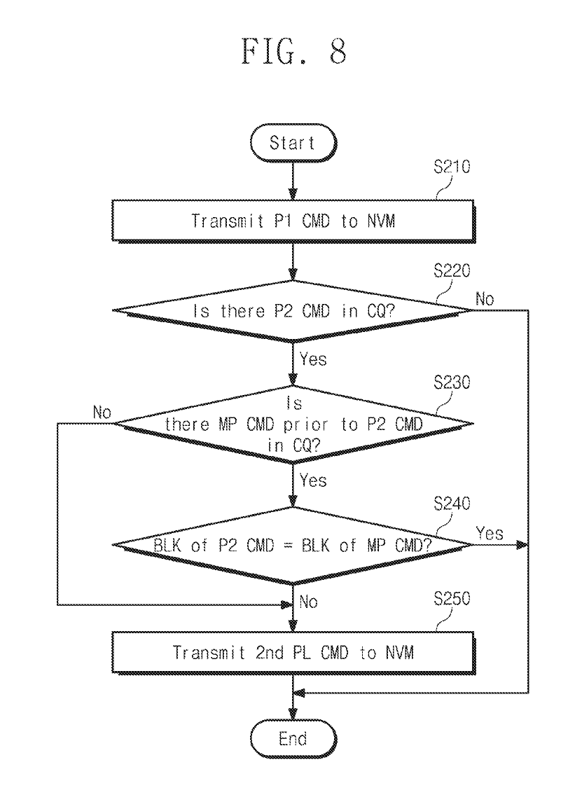

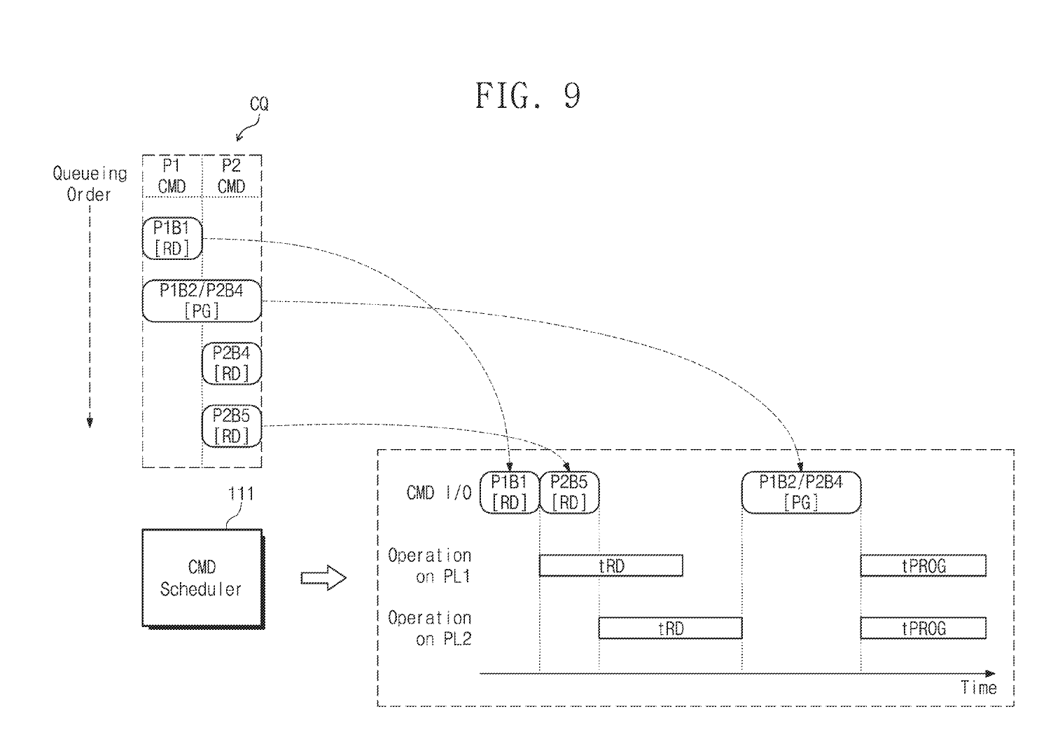

FIG. 8 is a flowchart illustrating an embodiment of an operation method of a command scheduler of FIG. 1. FIG. 9 is a view for explaining an operation method of FIG. 8. For brevity of drawings and convenience of description, configuration elements which are not necessary for explaining an operation method of FIG. 8 are omitted. A command configuration illustrated in FIG. 9 is described based on the reference numerals described with reference to FIG. 6. A queueing order of the command queue (CQ) illustrated in FIG. 9 is merely an example and the disclosure is not limited thereto.

Referring to FIGS. 1, 8 and 9, the command scheduler 111 may perform operations of S210 and S220. Since the operations of S210 and S220 are similar to the operations of S110 and S120 of FIG. 5, a description thereof is omitted.

In the case where there does not exist the P2 command in the command queue (CQ), the command scheduler 111 can sequentially schedule commands according to a queueing order in the command queue (CQ).

In the case where there exists the P2 command in the command queue (CQ), in an operation S230, the command scheduler 111 may determine whether there is an MP command ahead of the P2 command in the command queue (CQ). For example, various commands such as the P1 command, the P2 command, and the MP command may be sequentially queued in the command queue (CQ).

In a specific embodiment, referring to FIG. 9, the P1 command (P1B1[RD] command) may be first queued in the command queue (CQ) and then the MP command (P1B2/P2B4[PG] command) may be queued in the command queue (CQ). Thereafter, the P2 command (P2B4[RD] command and P2B5[RD] command) may be queued in the command queue (CQ). That is, there may exist the MP command between the P1 command transmitted to the nonvolatile memory device 120 and the P2 command described above. In this case, the command scheduler 111 may determine that there is the MP command ahead of the P2 command.

In the case where there is not the MP command ahead of the P2 command, the command scheduler 111 may perform an operation S250. Since the operation of S250 is similar to the operation of S130 of FIG. 5, a description thereof is omitted.

In the case where there is the MP command ahead of the P2 command, in an operation S240, the command scheduler 111 may compare a block address of the P2 command with a block address of the MP command. For example, the P2 command may include a block address of at least one of the fourth through sixth memory blocks (BLK4 to BLK6) of the second plane PL2. The MP command may include a block address of at least one of the first through third memory blocks (BLK1 to BLK3) of the first plane PL1 and a block address of at least one of the fourth through sixth memory blocks (BLK4 to BLK6) of the second plane PL2. The command scheduler 111 may compare a block address included in the P2 command with a block address of at least one of the fourth through sixth memory blocks (BLK4 to BLK6) of the second plane PL2 included in the MP command.

In the case where the block addresses described above are not identical to one another (or in the case where a block address of the MP command does not include a block address of the P2 command), in the operation S250, the command scheduler 111 may transmit the P2 command to the nonvolatile memory device 120.

In the case where the block addresses described above are identical to one another (or in the case where a block address of the MP command includes a block address of the P2 command), the P2 command and the MP command may be commands corresponding to an operation on the same memory block. In this case, the command scheduler 111 may not transmit the P2 command to the nonvolatile memory device 120 and sequentially schedule commands according to a queueing order in the command queue (CQ).

For example, it is assumed that the P2 command indicates a read operation on the fourth memory block BLK4 and the MP command indicates a program operation on the first memory block BLK1 and the fourth memory block BLK4. In this case, when each command is executed according to a queueing order, a program operation on the fourth memory block BLK4 may be performed by the MP command and then data programmed in the fourth memory block BLK4 may be read by the P2 command. However, in the case where the command scheduler 111 transmits the P2 command to the nonvolatile memory device 120 prior to the MP command, after unintended data is read in the fourth memory block BLK4 by the P2 command, the fourth memory block BLK4 may be programmed by the MP command.

More specifically, as illustrated in FIG. 9, the P1B1[RD] command (i.e., P1 command) may be transmitted to the nonvolatile memory device 120 by the command scheduler 111. The P2B4[RD] command (i.e., P2 command) and the P1B2/P2B4[PG] command (i.e., MP command) may include the same block address (i.e., a block address of the fourth memory block BLK4). In this case, the command scheduler 111 may not transmit the P2B4[RD] command to the nonvolatile memory device 120 before the P1B2/P2B4[PG] command Instead, the P2B5[RD] command and the P1B2/P2B4[PG] may include different block addresses (i.e., block addresses of the fourth and fifth memory blocks (BLK4, BLK5) respectively). In this case, the command scheduler 111 may transmit the P2B5[RD] command to the nonvolatile memory device 120 prior to the P1B2/P2B4[PG] command.

The command scheduler 111 compares the block address of the P2 command with the block address of the MP command queued prior to the P2 command In the case where the block address of the P2 command is different from the block address of the MP command, the command scheduler 111 may transmit the P2 command to the nonvolatile memory device 120 prior to the MP command In the case where the block address of the P2 command is the same as the block address of the MP command, the command scheduler 111 may transmit commands to the nonvolatile memory device 120 according to the queueing order (i.e., transmit the P2 command after transmitting the MP command) Accordingly, command processing time of the storage device 100 may be improved and an unintended operation (e.g., an operation of reading data different from the intended data) may be prevented.

In the embodiments described above, even though a configuration that compares the block address of the P2 command with the block address of the MP command was described, the scope of the disclosure is not limited thereto. For example, the command scheduler 111 may compare other physical addresses such as a row address, a page address, etc. instead of the block address and may perform the scheduling operation described above according to a comparison result.

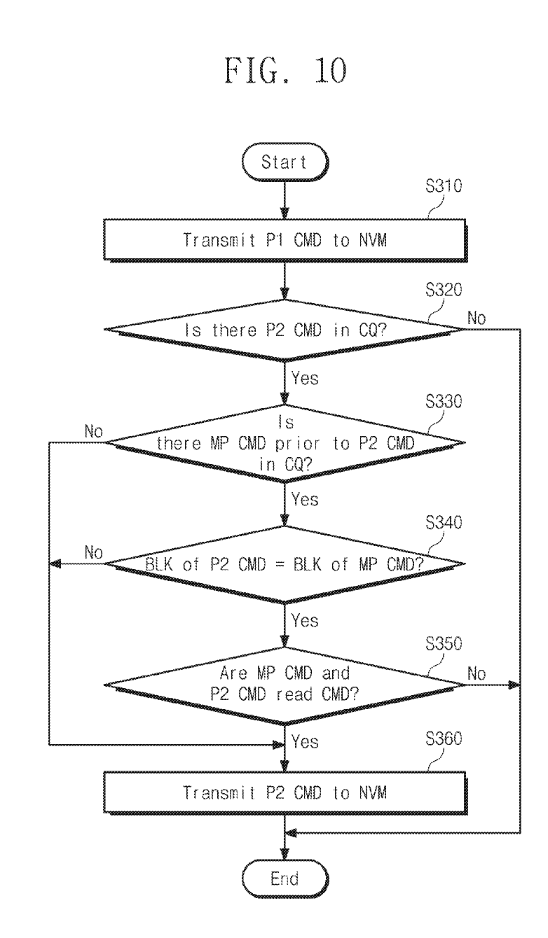

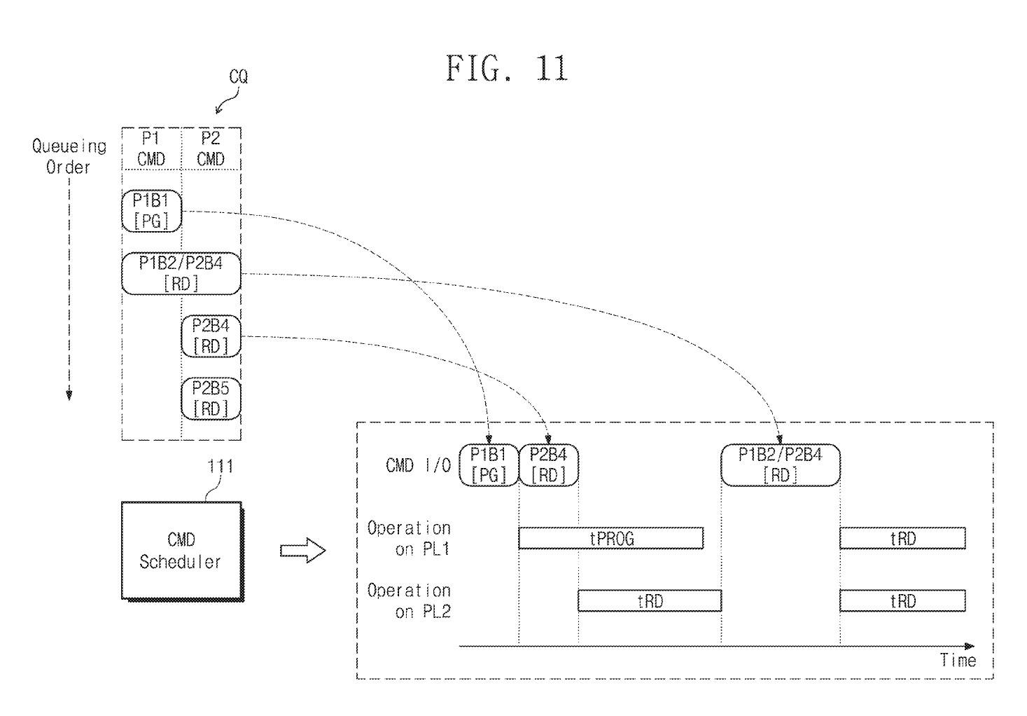

FIG. 10 is a flowchart illustrating another embodiment of an operation method of a command scheduler of FIG. 1. FIG. 11 is a view for explaining an operation method of FIG. 10. For brevity of drawing and convenience of description, configuration elements which are unnecessary for explaining an operation method of FIG. 10 are omitted. A command configuration illustrated in FIG. 11 is described based on the reference numerals described with reference to FIG. 6. A queueing order of the command queue (CQ) illustrated in FIG. 11 is merely an example and the disclosure is not limited thereto.

Referring to FIGS. 1, 10 and 11, the command scheduler 111 may perform operations of S310 through S340 and S360. Since the operations of S310 through S340 and S360 are respectively similar to the operations of S210 through S240 and S250 within FIG. 8, a description thereof is omitted.

In the case where a determination result of the operation S340 indicates that the block address of the P2 command is the same as the block address of the MP command, in an operation S350, the command scheduler 111 may determine whether the MP command and the P2 command are a read command.

In the case where the MP command and the P2 command are a read command, in an operation S360, the command scheduler 111 may transmit the P2 command to the nonvolatile memory device 120 prior to the MP command. In the case where at least one of the MP command and the P2 command is not a read command (i.e., at least one of the MP command and the P2 command is a program command or an erase command), the command scheduler 111 may not transmit the P2 command to the nonvolatile memory device 120 prior to the MP command.

For example, as illustrated in FIG. 11, the P1B1[PG] command (i.e., P1 command) may be transmitted to the nonvolatile memory device 120 by the command scheduler 111. The P2B4[RD] command (i.e., P2 command) and the P1B2/P2B4[RD] command (i.e., MP command) may include the same block address (i.e., an address of the fourth memory block BLK4). In this case, the command scheduler 111 may determine whether both of the P2 command and the MP command are a read command. As illustrated in FIG. 11, even though the P2B4[RD] command (i.e., P2 command) and the P1B2/P2B4[RD] command (i.e., MP command) may include the same block address (i.e., an address of the fourth memory block BLK4), in the case where both of the P2B4[RD] command (i.e., P2 command) and the P1B2/P2B4[RD] command (i.e., MP command) are a read command, the command scheduler 111 may transmit the P2B4[RD] command (i.e., P2 command) to the nonvolatile memory device 120 prior to the P1B2/P2B4[RD] command (i.e., MP command) In this case, even though the P2 command is transmitted to the nonvolatile memory device 120 prior to the MP command, since an operation of the P2 command and an operation of the MP command do not cause a data change, the operations may be normally performed regardless of the order.

However, if the P2 command is transmitted to the nonvolatile memory device 120 prior to the MP command under the situation that at least one of the MP command and the P2 command is not a read command, operations of the P2 command and the MP command may not be normally performed. In this case, the command scheduler 111 may transmit the MP command and the P2 command to the nonvolatile memory device 120 according to the queueing order.

As described above, in the case where the block address of the P2 command and the block address of the MP command that are included in the command queue (CQ) are different from each other, the command scheduler 111 may transmit the P2 command to the nonvolatile memory device 120 prior to the MP command In the case where the block address of the P2 command is the same as the block address of the MP command, the command scheduler 111 may determine whether both of the P2 command and the MP command are a read command In the case where both of the P2 command and the MP command are a read command, the command scheduler 111 may transmit the P2 command to the nonvolatile memory device 120 prior to the MP command.

Although not illustrated in the drawings, each operation of FIG. 10 may be performed in different order from order illustrated in FIG. 10 or a part of operations of FIG. 10 may be omitted. For example, the operation S350 may be performed before the operation S340, or the operation S340 may be omitted, but the scope of the disclosure is not limited thereto.

Accordingly, as described above, the command scheduler 111 may not only reduce command processing time but also guarantee a normal operation of each command by reordering a queueing order of the P1 command, the P2 command, and the MP command.

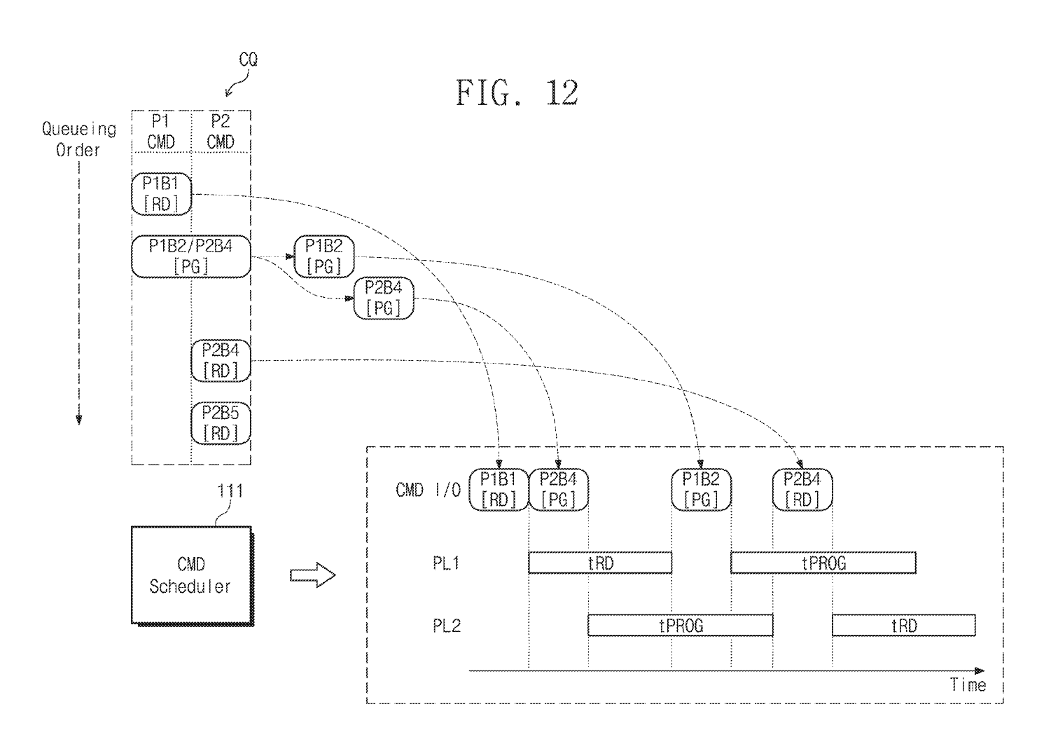

FIG. 12 is a view for explaining a different operation of a command scheduler of FIG. 1. For brevity of drawing and convenience of description, unnecessary configuration elements are omitted. Referring to FIGS. 1 and 12, the command scheduler 111 may be configured to divide the MP command into the P1 command and the P2 command.

As illustrated in FIG. 12, each command may be queued in the command queue (CQ) in the order of the P1B1[RD] command, the P1B2/P2B4[PG] command, the P2B4[RD] command, and the P2B5[RD] command. The command scheduler 111 may divide the P1B2/P2B4[PG] command which is the MP command into the P1B2[PG] command and the P2B4[PG] command.

As described above, the nonvolatile memory device 120 may support an independent operation by planes. Accordingly, the command scheduler 111 may process each of the P1B1[RD] command, the P1B2[PG] command, the P2B4[PG] command, the P2B4[RD] command, and the P2B5[RD] command based on the operation method described with reference to FIG. 5.

More specifically, the command scheduler 111 may transmit the P1B1[RD] to the nonvolatile memory device 120 according to the queueing order. After that, according to the operation method described with reference to FIG. 5, the command scheduler 111 may transmit the P2B4[PG] command separated from the P1B2/P2B4[PG] command to the nonvolatile memory device 120. After the nonvolatile memory device 120 completes a read operation on the P1B1[RD] command, the command scheduler 111 may transmit the P1B2[PG] command separated from the P1B2/P2B4[PG] command to the nonvolatile memory device 120. After the nonvolatile memory device 120 completes a program operation on the P2B4[PG] command, the command scheduler 111 may transmit the P2B4[RD] command to the nonvolatile memory device 120.

A conventional memory controller may process each of the commands of the command queue (CQ) illustrated in FIG. 12 according to the queueing order. That is, the conventional memory controller transmits the P1B1[RD] command to the nonvolatile memory device 120 and transmits the P1B2/P2B4[PG] command to the nonvolatile memory device 120 after the nonvolatile memory device 120 completes the P1B1[RD]. However, the command scheduler 111 of the memory controller 110 may divide the MP command into single plane commands (i.e., P1 command and P2 command) and may manage commands independently of each other by planes. Thus, time taken to process commands in the command queue (CQ) and overall performance of the storage device 100 may be improved.

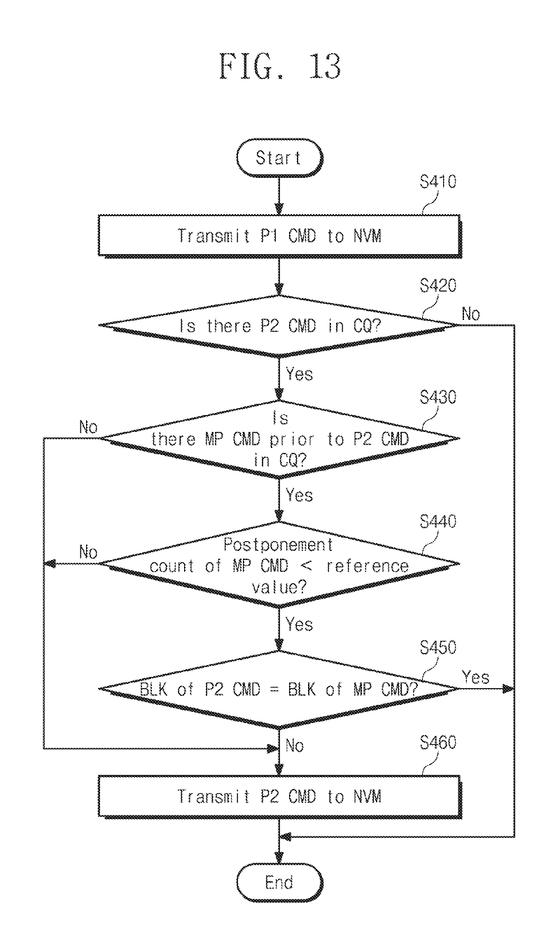

FIG. 13 is a flowchart illustrating a different operation of a command scheduler of FIG. 1. Referring to FIGS. 1 and 13, the command scheduler 111 may perform operations of S410 through S460. Since the operations of S410 through S430, S450, and S460 are respectively similar to the operations of S210 through S250 of FIG. 8 and the operations of S310 through S330, S340, and S360 of FIG. 10, a description thereof is omitted.

In the case where a determination result of the operation S430 indicates that there is a MP command prior to the P2 command, in an operation S440, the command scheduler 111 may determine whether a postponement count of the MP command is smaller than a reference value. For example, in the case where commands in the command queue (CQ) are processed according to the operation methods of the command scheduler 111 described above, under specific conditions, the P2 command or the P1 command having a later queueing order than the MP command may be processed prior to the MP command. In this case, the postponement count of the MP command may increase. In example embodiments, the postponement count may be managed by the command scheduler 111 or specific components.

In the case where the postponement count of the MP command is smaller than the reference value, the command scheduler 111 may perform operations of S450 and S460. In the case where the postponement count of the MP command is not smaller than the reference value, the command scheduler 111 may not transmit the P2 command to the nonvolatile memory device 120. In this case, the command scheduler 111 may process commands in the command queue (CQ) according to the queueing order.

The postponement count indicates the number of times a command later than the MP command is processed prior to the MP command or is transmitted to the nonvolatile memory device 120. For example, commands may be queued in the command queue (CQ) in the order of a first P1 command, a first MP command, a first P2 command, a second P1 command, and a second P2 command. The command scheduler 111 may transmit the first P1 command to the nonvolatile memory device 120 and may transmit the first P2 command to the nonvolatile memory device 120 prior to the first MP command. After an operation on the first P1 command is completed, the command scheduler 111 may transmit the second P1 command to the nonvolatile memory device 120 prior to the first MP command. In the case where commands are processed according to a general queueing order, the commands have to be processed in the order of the first P1 command, the first MP command, the first P2 command, the second P1 command, and the second P2 command. However, according to the scheduling method of the disclosure, the first MP command may be processed later than the second P1 command and the second P2 command In this case, the postponement count of the first MP command may be 2.

As described above, as the postponement count of the MP command increases, a process for the MP command may be delayed and thereby an error (e.g., an error caused by a command time out) may occur in an operation on the storage device 100. Thus, in the case where the postponement count of the MP command is greater than the reference value, the command scheduler 111 can prevent an incorrect operation caused by a postponement or delay of the MP command by not transmitting the P2 command to the nonvolatile memory device 120 and processing commands in the command queue (CQ) according to the queueing order.

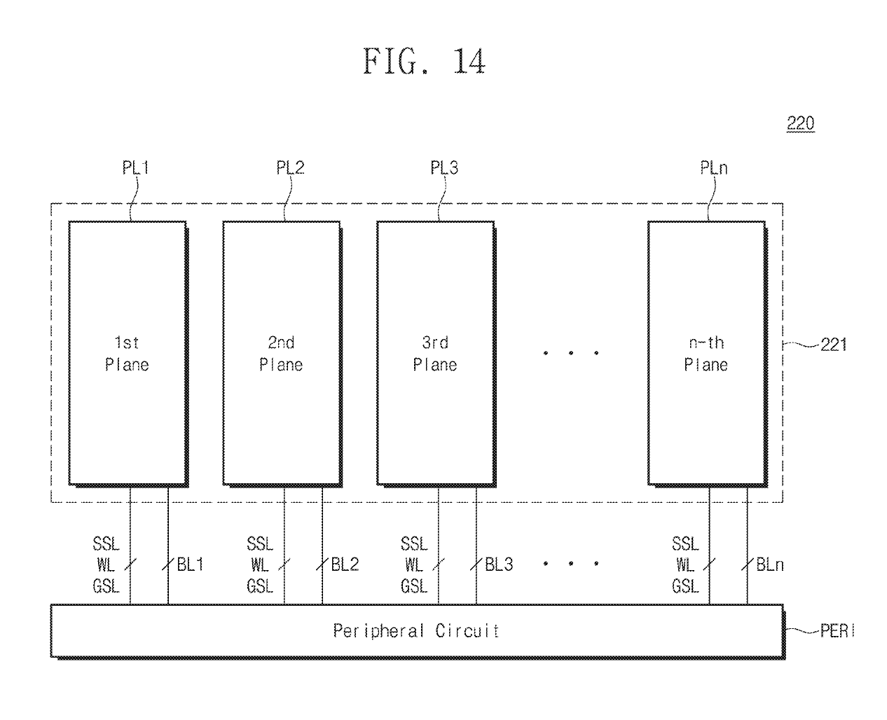

FIG. 14 is a block diagram illustrating a nonvolatile memory device according to other example embodiments of the disclosure. Referring to FIG. 14, a nonvolatile memory device 220 may include a memory cell array 221 and a peripheral circuit PERI.

The memory cell array 221 may include a plurality of planes (PL1 to PLn). Each of the planes (PL1 to PLn) may include a plurality of memory blocks. Each of the planes (PL1 to PLn) may be connected to the peripheral circuit PERI through string select line SSL, word lines WL, and ground select lines GSL.

The first plane PL1 may be connected to the peripheral circuit PERI through first bit lines BL1. Similarly, the second through nth planes (PL2 to PLn) may be connected to the peripheral circuit PERI through second through nth bit lines (BL2 to BLn) respectively. A plurality of memory blocks of the first plane PL1 may share the first bit lines BL1. Similarly, a plurality of memory blocks of the second through nth planes (PL2 to PLn) may share the respective second through nth bit lines (BL2 to BLn).

As described above, the nonvolatile memory device 220 may independently perform an operation on each of the planes (PL1 to PLn) under the control of the memory controller 110 (refer to FIG. 1). For example, the nonvolatile memory device 220 may perform a program operation on a second memory block included in the second plane PL2 while performing a read operation on a first memory block included in the first plane PL1.

The memory controller 110 described with reference to FIG. 1 may be configured to control the nonvolatile memory device 220 of FIG. 14. The memory controller 110 may schedule commands being transmitted to the nonvolatile memory device 220 based on the operation methods described with reference to FIGS. 1 through 13.

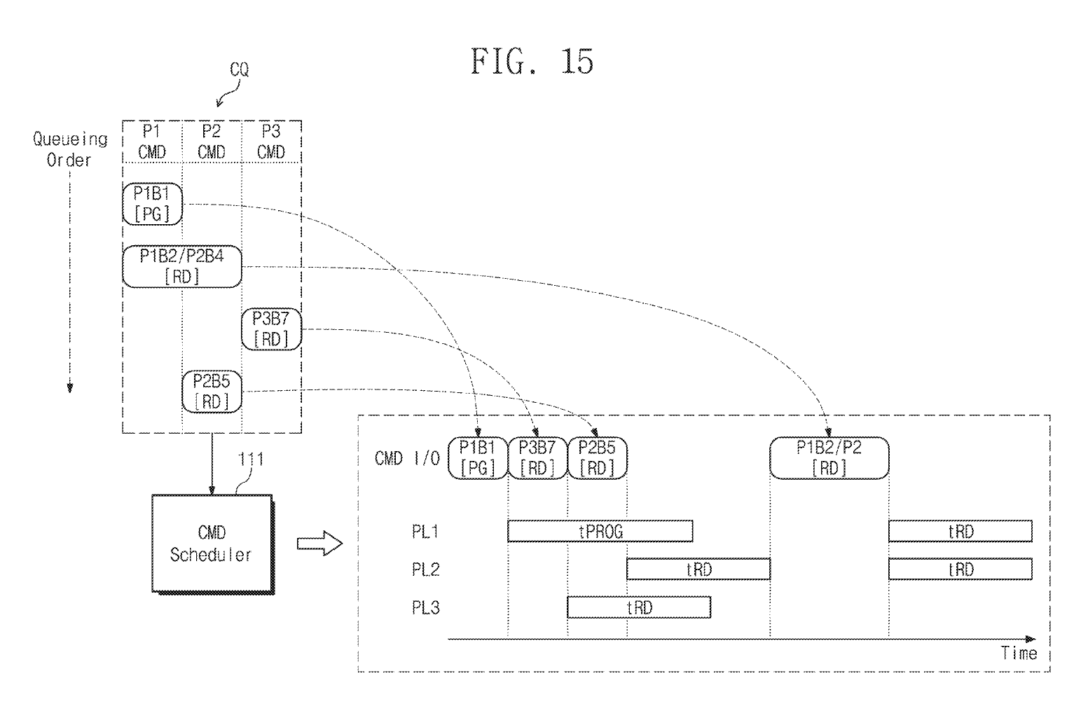

FIG. 15 is a view for explaining a scheduling method with respect to a command being provided to a nonvolatile memory device illustrated in FIG. 14. For brevity of description, configuration elements which are not necessary for describing a scheduling method with respect to commands provided to the nonvolatile memory device 220 of FIG. 14 are omitted.

For brevity of drawing and convenience of description, it may be understood that reference numerals of commands illustrated in FIG. 15 have a similar meaning to the reference numerals described with reference to FIG. 6. For brevity of description, an operation on each of the first through third planes (PL1, PL2, PL3) is described but the scope of the disclosure is not limited thereto. The operation may be changed to an operation on each of the planes (PL1 to PLn). The MP command illustrated in FIG. 15 is described based on an operation on two planes (PL1, PL2) but the scope of the disclosure is not limited thereto. The MP command may be a command with respect to two or more planes among the planes (PL1 to PLn).

Referring to FIGS. 14 and 15, commands may be queued in the command queue (CQ) in the order of the P1B1[PG] command, the P1B2/P2B4[RD] command, the P3B7[RD] command, and the P2B5[RD] command.

The command scheduler 111 may transmit the P1B1[PG] command to the nonvolatile memory device 120 similar to those described above. The nonvolatile memory device 120 may perform a program operation on the first plane PL1 (a first memory block of the first plane PL1) in response to the P1B1[PG] command A conventional memory controller may transmit the P1B2/P2B4[RD] command to the nonvolatile memory device 120 after the nonvolatile memory device 120 completes an operation on the P1B1[PG] command.

However, since the nonvolatile memory device 120 may independently operate on each plane, the command scheduler 111 of the memory controller 110 may transmit the P3B7 [RD] command to the nonvolatile memory device 120 prior to the P1B2/P2B4[RD] command before an operation on the P1B1[PG] command is completed. As described with reference to FIGS. 8 and 9, since a physical block address of the P2B5[RD] command and a physical block address of the P1B2/P2B4[RD] command prior to the P2B5[RD] command are different from each other, the command scheduler 111 may transmit the P2B5[RD] command to the nonvolatile memory device 220 prior to the P1B2/P2B4[RD].

As described above, unlike the conventional memory controller, the command scheduler 111 may process commands in an out-of-order manner. The command scheduler 111 may compare block addresses of commands included in the command queue (CQ) and may transmit the commands to the nonvolatile memory device 120 according to the aforementioned method based on a comparison result. Thus, since time taken to process commands is reduced, a storage device having improved performance is provided.

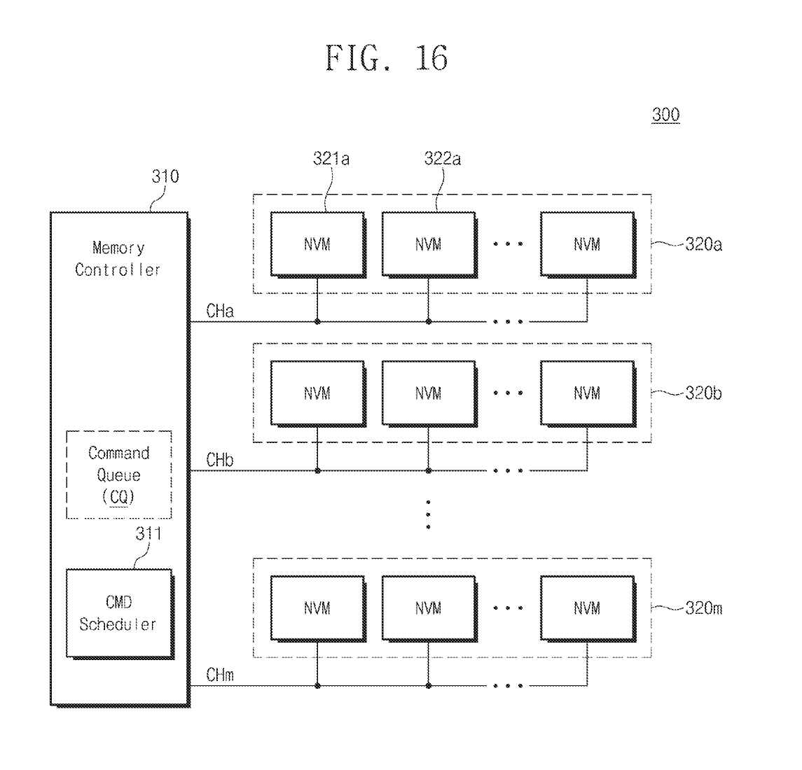

FIG. 16 is a view illustrating a storage device according to example embodiments of the disclosure. Referring to FIG. 16, a storage device 300 may include a memory controller 310 and a plurality of nonvolatile memory devices (320a to 320m). The memory controller 310 may include a command queue (CQ) and a command scheduler 311. Since the plurality of nonvolatile memory devices (320a to 320m), the command queue (CQ), and the command scheduler 311 were described with reference to FIGS. 1 through 15, a description thereof is omitted.

The plurality of nonvolatile memory devices (320a to 320m) may be connected to the memory controller 310 through a plurality of channels (CHa to CHm) respectively. For example, the nonvolatile memory device 320a may be connected to the memory controller 310 through the first channel CHa. Similarly, the nonvolatile memory devices (320b to 320m) may be connected to the memory controller 310 through the respective second through mth channels (CHb to CHm).

The memory controller 310 can independently control nonvolatile memory devices by channels. Although not illustrated in the drawing, the command queue (CQ) and the command scheduler 311 with respect to each of the channels (CHa to CHm) may independently exist.

The memory controller 310 can independently control nonvolatile memory devices connected through one channel. For example, the memory controller 310 may transmit a command to or exchange data with a first nonvolatile memory device 321a through the first channel CHa and may transmit a command to or exchange data with a second nonvolatile memory device 322a through the first channel CHa.

The memory controller 310 may process commands included in the command queue (CQ) with respect to one nonvolatile memory device based on the scheduling method described with reference to FIGS. 1 through 15.

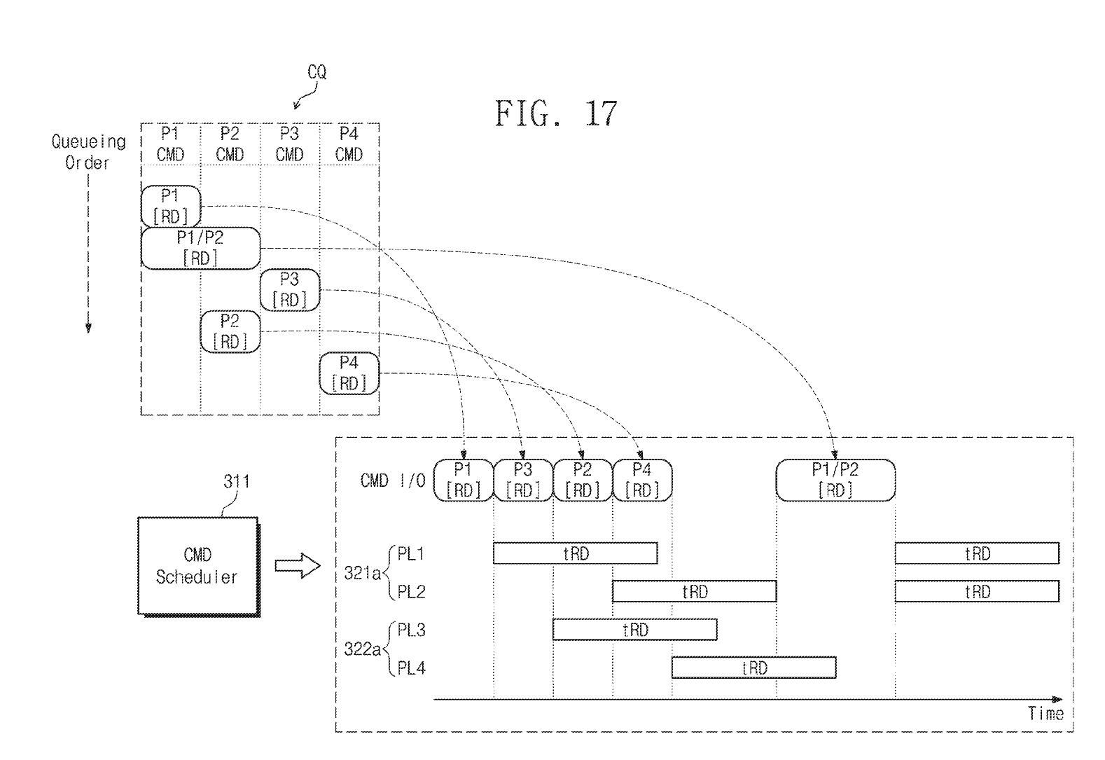

FIG. 17 is a view for explaining a command scheduling method with respect to a storage device of FIG. 16. For brevity of drawing and convenience of description, an embodiment of FIG. 17 will be described based on the first and second nonvolatile memory devices (321a, 322a) connected to the memory controller 310 through the first channel CHa. It is assumed that the first nonvolatile memory device 321a includes first and second planes (PL1, PL2) and the second nonvolatile memory device 322a includes third and fourth planes (PL3, PL4).

For brevity of drawing and convenience of description, commands illustrated in FIG. 17 are written with reference to a reference number of each plane and information about a block number or a block address is omitted from the reference number. For example, a read command with reference to the first plane PL1 is marked as a P1[RD] command and a read command (i.e., a multi-plane read command) with reference to the first and second planes (PL1, PL2) is marked as a P1/P2[RD] command. For brevity of drawings and convenience of description, it is assumed that block addresses included in the commands are different from one another. Each command may include the same block address and in this case, as described with reference to FIGS. 1 through 13, a processing order may be changed depending on the type (e.g., read, program, erase, etc.) of commands.

The assumptions described above do not limit the scope of the disclosure and each of the first and second nonvolatile memory devices (321a, 322a) may include a plurality of planes. A command scheduling method that will be described below may be changed or extended with respect to a plurality of nonvolatile memory devices,

Referring to FIG. 17, commands may be queued in the command queued (CQ) in the order of P1[RD] command, P1/P2[RD] command, P3[RD] command, P2[RD] command, and P4[RD] command. As before described, the P1[RD] command indicates a read command with respect to the first plane PL1, the P1/P2[RD] command indicates a read command with respect to the first and second planes (PL1, PL2), the P3[RD] command indicates a read command with respect to the third plane PL3, the P2[RD] command indicates a read command with respect to the second plane PL2, and the P4[RD] command indicates a read command with respect to the fourth plane PL4.

As illustrated in FIGS. 16 and 17, the command scheduler 311 may transmit the P1 [RD] command to the first nonvolatile memory device 321a through the first channel CHa (e.g., a CMD I/O of the first channel CHa). The first nonvolatile memory device 321a may perform a read operation on the first plane PL1 in response to the P1[RD] command.

The command scheduler 311 may transmit the P3 [RD] command to the second nonvolatile memory device 322a. As before described, since the first and second nonvolatile memory devices (321a, 322a) operate independently of each other, the command scheduler 311 may transmit the P3[RD] command to the second nonvolatile memory device 322a while the first nonvolatile memory device 321a performs a read operation (i.e., a read operation according to the P1[RD] command) The second nonvolatile memory device 322a may perform a read operation on the third plane PL3 in response to the P3 [RD] command.

The command scheduler 311 may transmit the P2[RD] command to the first nonvolatile memory device 321a. As before described, the first and second planes (PL1, PL2) of the first nonvolatile memory device 321a may operate independently of each other. The command scheduler 311 may transmit the P2[RD] command to the first nonvolatile memory device 321a while the first nonvolatile memory device 321a performs a read operation on the first plane PL1. The first nonvolatile memory device 321a may perform a read operation on the second plane PL2 in response to the P2[RD] command. As before described, the P1/P2[RD] command may not include a block address of the P2[RD] command.

The command scheduler 311 may transmit the P4[RD] command to the second nonvolatile memory device 322a and the second nonvolatile memory device 322a may perform a read operation on the fourth plane PL4 in response to the P4[RD] command.

After read operations on the first and second planes (PL1, PL2) of the first nonvolatile memory device 321a are all completed, the command scheduler 311 may transmit the P1/P2[RD] command to the first nonvolatile memory device 321a. The first nonvolatile memory device 321a may perform a read operation on the first and second planes (PL1, PL2) in response to the P1/P2[RD] command.

A conventional memory controller, with respect to the command queue (CQ) illustrated in FIG. 17, transmits the P1[RD] command to the first nonvolatile memory device 321a and then transmits the P1/P2[RD] command to the first nonvolatile memory device 321a after an operation according to the P1[RD] command is completed. The conventional memory controller may transmit the P2[RD] command to the first nonvolatile memory device 321a after an operation according to the P1/P2[RD] command is completed. The command scheduler 311 can reduce overall command processing time by comparing physical addresses of a single plane command and a multi plane command with respect to each nonvolatile memory device and transmitting the single plane command to the nonvolatile memory device prior to the multi plane command according to a comparison result.

The embodiment illustrated in FIG. 17 is illustrative and the scope of the disclosure is not limited thereto. The command scheduler may process commands in the command queue (CQ) according to the scheduling method described with reference to FIGS. 1 through 16 by channels, ways, or chips.

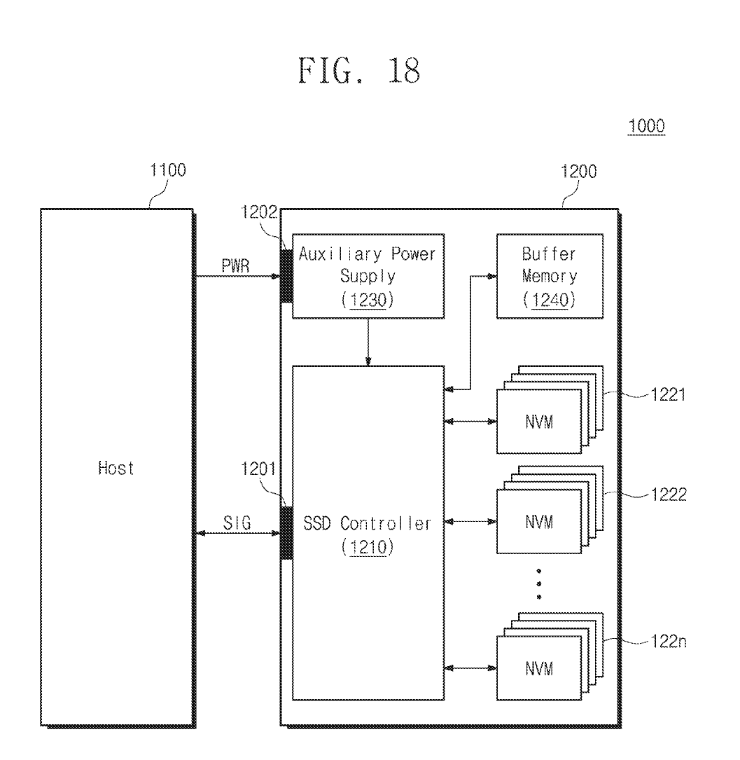

FIG. 18 is a block diagram illustrating an SSD (solid state drive) system to which the disclosure is applied. Referring to FIG. 18, an SSD system 1000 includes a host 1100 and an SSD 1200.

The SSD 1200 may exchange a signal SIG with the host 1100 through a signal connector 1201 and receive power PWR through a power connector 1202. The SSD 1200 may include an SSD controller 1210, a plurality of flash memories 1221-122n, an auxiliary power supply 1230, and a buffer memory 1240.

The SSD controller 1210 may control the flash memories 1221-122n in response to the signal SIG received from the host 1100. The flash memories 1221-122n may operate under the control of the SSD controller 1210. The SSD controller 1210 may include the command queue (CQ) and the command scheduler (111, 311) described with reference to FIGS. 1 through 17. As described with reference to FIGS. 1 through 17, each of the flash memories 1221-122n may be configured to include a plurality of planes and perform an independent operation by planes. The SSD controller 1210 can control each of the flash memories 1221-122n according to the scheduling method described with reference to FIGS. 1 through 17.

The auxiliary power supply 1230 is connected to the host 1100 through the power connector 1202. The auxiliary power supply 1230 may receive power PWR from the host 1100 to charge the auxiliary power supply 1230. The auxiliary power supply 1230 may provide power of the SSD 1200 when a power supply from the host 1100 is not smooth.

The buffer memory 1240 operates as a buffer memory of the SSD 1200. The buffer memory 1240 may temporarily store data received from the host 1100, data received from the flash memories 1221-122n, or meta data (e.g., mapping table) of the flash memories 1221-122n. The buffer memory 1240 may temporarily store various information required when the SSD controller 1210 operates.

According to the embodiments of the disclosure, by comparing block addresses of a single plane command and a multi plane command to reorder an order of the commands, a method of operating a memory controller having improved performance and a method of operating a storage device including the memory controller are provided.

As is traditional in the field, embodiments may be described and illustrated in terms of blocks which carry out a described function or functions. These blocks, which may be referred to herein as units or modules or the like, are physically implemented by analog and/or digital circuits such as logic gates, integrated circuits, microprocessors, microcontrollers, memory circuits, passive electronic components, active electronic components, optical components, hardwired circuits and the like, and may optionally be driven by firmware and/or software. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

The contents described above are specific embodiments for implementing the disclosure. The disclosure may include not only the embodiments described above but also embodiments in which a design is simply or easily capable of being changed. The disclosure may also include technologies easily changed to be implemented using embodiments. Thus, the scope of the disclosure is to be determined by the following claims and their equivalents, and shall not be restricted or limited by the foregoing embodiments.

What is claimed is:

1. A method of operating a memory controller that controls a nonvolatile memory device including first and second planes, the method comprising:
transmitting a first command included in a command queue to the nonvolatile memory device;
comparing a block address of a second command with a block address of a third command when the third command is ahead of the second command in the command queue; and
selectively transmitting the second command to the nonvolatile memory device prior to the third command based on the comparison result, wherein
the first command is a command with respect to the first plane, the second command is a command with respect to the second plane, and the third command is a multi-plane command with respect to the first and second planes.

2. The method of claim 1, wherein selectively transmitting the second command to the nonvolatile memory device prior to the third command based on the comparison result comprises transmitting the second command to the nonvolatile memory device prior to the third command before receiving a response to the first command from the nonvolatile memory device.

3. The method of claim 1, wherein selectively transmitting the second command to the nonvolatile memory device prior to the third command based on the comparison result comprises transmitting the second command to the nonvolatile memory device prior to the third command when the block address of the third command does not include the block address of the second command.

4. The method of claim 1, wherein selectively transmitting the second command to the nonvolatile memory device prior to the third command based on the comparison result comprises transmitting the third command to the nonvolatile memory device prior to the second command when the block address of the third command includes the block address of the second command.

5. The method of claim 4, wherein transmitting the third command to the nonvolatile memory device prior to the second command is performed after receiving a response to the first command from the nonvolatile memory device.

6. The method of claim 1, wherein selectively transmitting the second command to the nonvolatile memory device prior to the third command based on the comparison result comprises:
determining whether both of the second command and the third command are a read command when the block address of the third command includes the block address of the second command; and
selectively transmitting the second command to the nonvolatile memory device prior to the third command based on the determination result.

7. The method of claim 6, wherein selectively transmitting the second command to the nonvolatile memory device prior to the third command based on the determination result comprises transmitting the second command to the nonvolatile memory device prior to the third command when both of the second command and the third command are the read command.

8. The method of claim 6, wherein selectively transmitting the second command to the nonvolatile memory device prior to the third command based on the determination result comprises transmitting the third command to the nonvolatile memory device prior to the second command when at least one of the second command and the third command is not the read command.

9. The method of claim 1, wherein selectively transmitting the second command to the nonvolatile memory device prior to the third command based on the comparison result comprises:
determining whether a postponement count of the third command is smaller than a reference value when the block address of the third command does not include the block address of the second command; and
transmitting the second command to the nonvolatile memory device prior to the third command when the postponement count is smaller than the reference value, and transmitting the third command to the nonvolatile memory device prior to the second command when the postponement count is not smaller than the reference value.

10. The method of claim 1, further comprising transmitting the third command to the nonvolatile memory device after receiving a response to the first command and a response to the second command from the nonvolatile memory device.

11. The method of claim 1, wherein each of the first and second planes comprises a plurality of memory blocks, the plurality of memory blocks of the first plane share first bit lines and the plurality of memory blocks of the second plane share second bit lines.

12. An operation method of a storage device including a nonvolatile memory device, which includes first and second planes, and a memory controller that controls the nonvolatile memory device, the method comprising:
processing a first command included in a command queue of the memory controller;
comparing a block address of a second command with a block address of a third command when the third command is ahead of the second command; and
processing the second command prior to the third command according to the comparison result, wherein
the first command is a command with respect to the first plane, the second command is a command with respect to the second plane, and the third command is a command with respect to the first and second planes.

13. The operation method of claim 12, wherein processing the first command comprises performing an operation on the first plane by the nonvolatile memory device.

14. The operation method of claim 12, wherein processing the second command prior to the third command according to the comparison result comprises processing the second command prior to the third command when the block address of the third command does not comprise a part of the block address of the second command.

15. The operation method of claim 12, wherein processing the second command prior to the third command according to the comparison result comprises processing the third command prior to the second command when the block address of the third command comprises a part of the block address of the second command.

16. A method executed by a storage device comprising a memory controller and a nonvolatile memory, the method comprising:
communicating a first command from the memory controller to the nonvolatile memory, the first command having a highest execution priority within a command queue of the memory controller; and
when a second command having the next-highest priority, to that of the first command, within the command queue is addressed to the same plane of the nonvolatile memory as is the first command, communicating a third command within the command queue from the memory controller to the nonvolatile memory that is not addressed to the same plane of the nonvolatile memory as is the first command and otherwise communicating the second command from the memory controller to the nonvolatile memory.

17. The method of claim 16, further comprising concurrently executing, within the nonvolatile memory, either the first and second commands or the first and third commands.

18. The method of claim 16, wherein no two planes of the nonvolatile memory address one or more memory cells of the nonvolatile memory with the same bit line.

19. The method of claim 16, wherein each of the second and third commands are separable commands of a multiplane command that controls operations by the nonvolatile memory on two distinct planes of the nonvolatile memory.

20. The method of claim of claim 19, further comprising withholding communication of the second command to the nonvolatile memory until execution of the first command by the nonvolatile memory is complete.
